(19) United States
(12) Patent Application Publication
(10) Pub. No.: US 2010/0181584 A1
(43) Pub. Date: Jul. 22, 2010

(54) LASER LIFT-OFF WITH IMPROVED LIGHT EXTRACTION

(76) Inventors: Xiang Gao, Edison, NJ (US); Hari S. Venugopalan, Bridgewater, NJ (US); Michael Sackrison, Bethlehem, PA (US); Ivan Eliashevich, Maplewood, NJ (US)

Correspondence Address: FAY SHARPE LLP, 1228 Euclid Avenue, 5th Floor, The Halle Building, Cleveland, OH, 44115, US

(21) Appl. No.: 12/304,533

(22) PCT Filed: Jul. 11, 2006
(86) PCT No.: PCT/US06/27205

§ 371 Date: Mar. 30, 2010

Related U.S. Application Data
(60) Provisional application No. 60/698,032, filed on Jul. 11, 2005.

(51) Int. Cl. H01L 33/00; H01L 31/00

(52) U.S. Cl. 257/98; 438/29; 257/E33.073; 257/E31.001

(57) ABSTRACT

A light emitting device includes a stack of semiconductor layers defining a light emitting pn junction and a dielectric layer disposed over the stack of semiconductor layers. The dielectric layer has a refractive index substantially matching a refractive index of the stack of semiconductor layers. The dielectric layer has a principal surface distal from the stack of semiconductor layers. The distal principal surface includes patterning, roughening, or texturing configured to promote extraction of light generated in the stack of semiconductor layers.

### BACKGROUND

The following relates to the lighting arts. It especially relates to light emitting devices including group III-nitride based light emitting diodes (LEDs) transferred from a deposition substrate to a host substrate or sub-mount using a laser lift-off process, and to methods for fabricating same, and will be described with particular reference thereto. However, the following will also find application in conjunction with other light emitting semiconductor devices that include semiconductor layers transferred from a deposition substrate to a host substrate or sub-mount.

Group III-nitride based LEDs are used for generating green, blue, violet, and ultraviolet light emission. These LEDs include a stack of layers typically including layers of gallium nitride (GaN), aluminum nitride (AlN), indium nitride (InN), and ternary or quaternary alloys thereof, which define a pn diode. By coupling such an

LED with suitable phosphors, a white LED can be fabricated. For example, the LED die can be coated with a phosphor-containing encapsulant, an array of group Ill-nitride based LEDs can be arranged to irradiate a phosphor-containing or phosphor-coated optic, or so forth.

The deposition substrate for epitaxially growing the group III-nitride layers should substantially comport with the lattice constant, growth temperature, and chemistry of the epitaxially deposited group III-nitride layers. The ideal substrate is a group III-nitride substrate such as a GaN substrate; however, difficulties have been encountered in generating large-area group III-nitride wafers. Most group III-nitride LEDs are presently grown on deposition substrates made of sapphire Al₂O₃)(or silicon carbide (SiC).

Sapphire and SiC have characteristics that may not be advantageous in the finished device, such as being electrically insulating, exhibiting limited thermal conductivity, or so forth. Accordingly, there is interest in transferring the epitaxially grown group III-nitride pn diode stack from the deposition substrate to a more advantageous host substrate or sub-mount, which provides structural support (and optionally also electrical connectivity) for the final fabricated LED device. Suitable host substrates or sub-mounts can include, for example, silicon or gallium arsenide (GaAs) substrates or sub-mounts, a dielectric-coated metal substrate or sub-mount, or so forth. To perform the lift-off, the surface of the epitaxially grown group III-nitride stack is attached to the host substrate or sub-mount and detached from the sapphire, SiC, or other deposition substrate.

One approach for detaching the stack of group III-nitride semiconductor layers is application of a laser lift-off process. Laser lift-off detachment processes employ a laser whose energy is absorbed near the interface between the group III-nitride stack and the deposition substrate. For example, some excimer lasers produce laser beams that are highly transparent in sapphire but strongly absorbed by GaN. With the group III-nitride layers bonded to the host substrate, the excimer laser impinges upon the sapphire substrate. Because the sapphire is transparent to the laser beam, it passes through the sapphire substrate substantially without attenuation, and is absorbed at the GaN/sapphire interface, causing detachment of the sapphire substrate.

Although laser lift-off provides a host substrate or sub-mount having advantageous characteristics, light extraction from the detached stack of group III-nitride layers is degraded by the lift-off. The lifted-off stack of group III-nitride layers is thin (typical thicknesses for the stack are around a few microns to around a few tens of microns) with substantially larger lateral dimensions (typically hundreds of microns to a centimeter or larger). The new surface created by the laser lift-off is smooth. Moreover, the refractive index of group III-nitride materials is high. The high aspect ratio dimensions, smooth surface, and high refractive index cooperate to cause substantial total internal reflection and waveguiding of light generated in the lifted-off stack of group Ill-nitride layers; which substantially reduces light extraction.

### BRIEF SUMMARY

According to one aspect, a light emitting device is disclosed, including a stack of semiconductor layers defining a light emitting pn junction and a dielectric layer disposed over the stack of semiconductor layers. The dielectric layer has a refractive index substantially matching a refractive index of the stack of semiconductor layers. The dielectric layer has a principal surface distal from the stack of semiconductor layers. The distal principal surface includes patterning, roughening, or texturing configured to promote extraction of light generated in the stack of semiconductor layers.

According to another aspect, a method is disclosed for fabricating a light emitting device. A stack of semiconductor layers is formed defining a light emitting pn junction. A dielectric layer is disposed over the stack of semiconductor layers. The dielectric layer has a refractive index substantially matching a refractive index of the stack of semiconductor layers. The dielectric layer has a principal surface distal from the stack of semiconductor layers. The distal principal surface includes patterning, roughening, or texturing configured to promote extraction of light generated in the stack of semiconductor layers.

According to another aspect, a light emitting device is disclosed, including a stack of semiconductor layers defining a light emitting pn junction and a host substrate or sub-mount on which is disposed the stack of semiconductor layers. The host substrate or sub-mount is different from a deposition substrate on which the stack of semiconductor layers was formed. Patterning, roughening, or texturing configured to promote extraction of light generated in the stack of semiconductor layers is formed, on a distal principal surface of the stack of semiconductor layers that is distal from the host substrate or sub-mount.

According to another aspect, a method is disclosed for fabricating a light emitting device. A stack of semiconductor layers defining a light emitting pn junction is formed on a deposition substrate. The formed stack of semiconductor layers is transferred from the deposition substrate to a host substrate or sub-mount. The transferring exposes a new principal surface of the stack of semiconductor layers that was not exposed when the stack of semiconductor layers was formed on the deposition substrate. Patterning, roughening, or texturing configured to promote extraction of light generated in the stack of semiconductor layers is generated on the new principal surface of the stack of semiconductor layers.

### BRIEF DESCRIPTION OF THE DRAWINGS

FIGS. 1A-1D diagrammatically show a suitable group III-nitride LED fabrication process including laser lift-off processing. FIG. 1A diagrammatically shows a stack of semiconductor layers deposited on a deposition substrate. FIG. 1B diagrammatically shows the stack of semiconductor layers attached to a host substrate or sub-mount during laser lift-off of the deposition substrate. FIG. 1C diagrammatically shows the stack of semiconductor layers attached to the host substrate or sub-mount after detachment of the deposition substrate. FIG. 1D diagrammatically shows the fabricated light emitting device, including a dielectric layer disposed over the stack of semiconductor layers having a distal principal surface including patterning, roughening, or texturing configured to promote extraction of light generated in the stack of semiconductor layers.

FIG. 2 diagrammatically shows another embodiment of the fabricated light emitting device, in which the dielectric layer includes openings extending through to expose portions of the stack of semiconductor layers, the openings defining the patterning, roughening, or texturing of the distal principal surface.

### DETAILED DESCRIPTION OF PREFERRED EMBODIMENTS

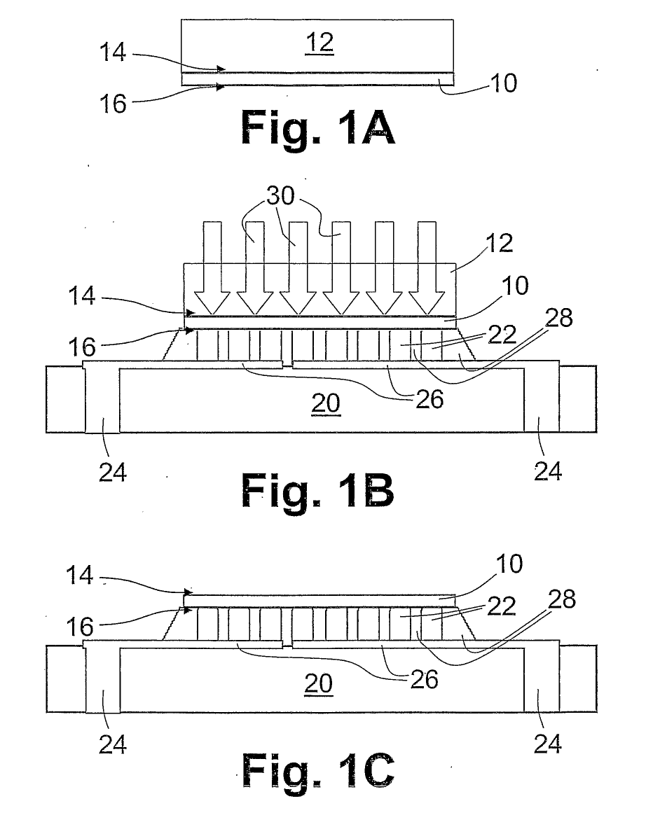

With reference to FIGS. 1A-1D, an LED is fabricated as follows. A stack of group III-nitride semiconductor layers 10 defining a light-emitting pn junction is deposited on a deposition substrate 12. In some embodiments, the stack of group III-nitride semiconductor layers 10 defining a light-emitting pn junction include semiconductor layers selected from a group consisting of: a gallium nitride (GaN) layer, an aluminum nitride (AlN) layer, an indium nitride (InN) layer, layers comprising ternary alloys of GaN, AlN, or InN, and layers comprising quaternary alloys of GaN, AN, and InN. However, other semiconductor layers can be formed instead of or in addition to group III-nitride layers. For example, the stack of group III-nitride layers can include group III-phosphide layers, group III-arsenide layers, group IV semiconductor layers, or so forth. The pn junction can be an interface, or can include layers defining an active region. For example, the pn junction can include a multi-quantum well region including a plurality of layers containing InN or alloys thereof. For group III-nitride semiconductor layers, the depositing can be done using metal-organic chemical vapor deposition (MOCVD), molecular beam epitaxy (MBE), hydride vapor phase epitaxy (HYPE), or so forth.

In some embodiments, the deposition substrate 12 is sapphire or SiC, which are advantageously closely lattice-matched to GaN. However, other deposition substrates can be used. The deposition substrate should be closely lattice-matched to the stack of group III-nitride semiconductor layers. However, some lattice mismatch therebetween can be tolerated. Optionally, techniques such as graded epitaxial semiconductor buffers or use of thin, compliant deposition substrates can be employed to accommodate lattice mismatch between the deposited stack and the deposition substrate.

FIG. 1A shows the stack of group III-nitride semiconductor layers 10 formed on the deposition substrate 12. The formed stack of group III-nitride semiconductor layers 10 includes a first principal surface 14 by which the stack 10 is secured -to the deposition substrate 12 during deposition, and a second principal surface 16 which is distal from the deposition substrate 12.

After formation, the second principal surface 16 of the stack of group III-nitride semiconductor layers 10 is attached to a host substrate or sub-mount 20, such as a silicon sub-mount. The illustrated host substrate or sub-mount 20 includes bonding bumps 22 electrically connecting with the stack of semiconductor layers 10 to enable electrical energizing of the light-emitting pn junction. Typically, the bonding bumps 22 electrically contact metallic or other highly conductive electrode layers (not shown) which were deposited on the second principal surface 16 of the stack of semiconductor layers 10 prior to the attachment. The illustrated host substrate or sub-mount 20 further includes conductive vias 24 electrically connected with the bonding bumps 22 by front-side conductive traces 26 so as to provide back-side electrical contact for the device. Optionally, an underfill material 28 is disposed between the attached stack of semiconductor layers 10 and the host substrate or sub-mount 20 in-between the bonding bumps 22. The underfill material can provide benefits such as improved attachment, thermal conduction from the stack of semiconductor layers 10 to the host substrate or sub-mount 20, or so forth. The underfill material 28 should be electrically insulating, and can be either thermally insulating, or thermally conductive to promote heat transfer from the stack of semiconductor layers 10 to the host substrate or sub-mount 20.

After attachment of the second principal surface 16 of the stack of group III-nitride semiconductor layers 10 to the host substrate or sub-mount 20, the stack of group La-nitride semiconductor layers 10 is detached from the deposition substrate 12. In some embodiments, laser lift-off is used to effectuate this detachment. In a suitable laser lift-off approach, a laser beam 30 (diagrammatically indicated by block arrows in FIG. 1B) is applied to the deposition substrate 12. While the conventional term “laser” is used herein in referencing the laser lift-off process, it is intended that the term “laser” as used herein encompasses both a conventional laser light source such as an excimer laser, or a focused high-intensity arc lamp light source, a focused high-intensity incandescent light source, or other high-intensity light source. The wavelength or photon energy of the laser beam 30 is selected to be substantially transparent for the deposition substrate 12 such that the laser beam 30 passes through the deposition substrate 12 substantially unattenuated. The wavelength or photon energy of the laser beam 30 is further selected to be strongly absorbed by one or more materials of the stack of group III-nitride semiconductor layers 10, so that the laser beam 30 is absorbed proximate to the first principal surface 14 of the stack of semiconductor layers 10 to cause detachment of the deposition substrate 12 from the stack of semiconductor layers 10.

FIG. 1B diagrammatically illustrates the application of the laser beam 30 during the laser lift-off process. FIG. 1C diagrammatically illustrates the light emitting device after the laser lift-off. At the point in processing illustrated in FIG. 1C, the second principal surface 16 of the stack of semiconductor layers 10 is attached to the host substrate or sub-mount 20, while the first principal surface 14 is exposed by the detachment of the deposition substrate 12. Typically, the exposed first principal surface 14 is relatively smooth. In some embodiments, the exposed first principal surface 14 has an RMS roughness of a few nanometers to a few microns. This relatively smooth exposed first principal surface 14 promotes total internal reflection of light generated in the stack of semiconductor layers 10 at the first principal surface 14, and promotes waveguiding that traps light within the stack of semiconductor layers 10. These effects degrade the light extraction efficiency.

With reference to FIG. 1D, a dielectric layer 40 is disposed over the stack of semiconductor layers 10. The dielectric layer 40 is substantially transparent to light emitted by the stack of semiconductor layers 10, and has a refractive index that substantially matches a refractive index of the stack of semiconductor layers 10. The dielectric layer 40 includes a proximate principal surface 42 that is in contact with the stack of semiconductor layers 10, and a distal principal surface 44 distal from the stack of semiconductor layers 10. The distal principal surface 44 includes patterning, roughening, or texturing 50 configured to promote extraction of light generated in the stack of semiconductor layers. In the embodiment of FIG. 1D, the patterning, roughening, or texturing 50 extends only partway through the dielectric layer 40. Accordingly, the proximate principal surface 42 does not include the patterning, roughening, or texturing 50 of the distal principal surface 44. Rather, the proximate principal surface 42 is continuous and covers the first principal surface 14 of the stack of semiconductor layers 10.

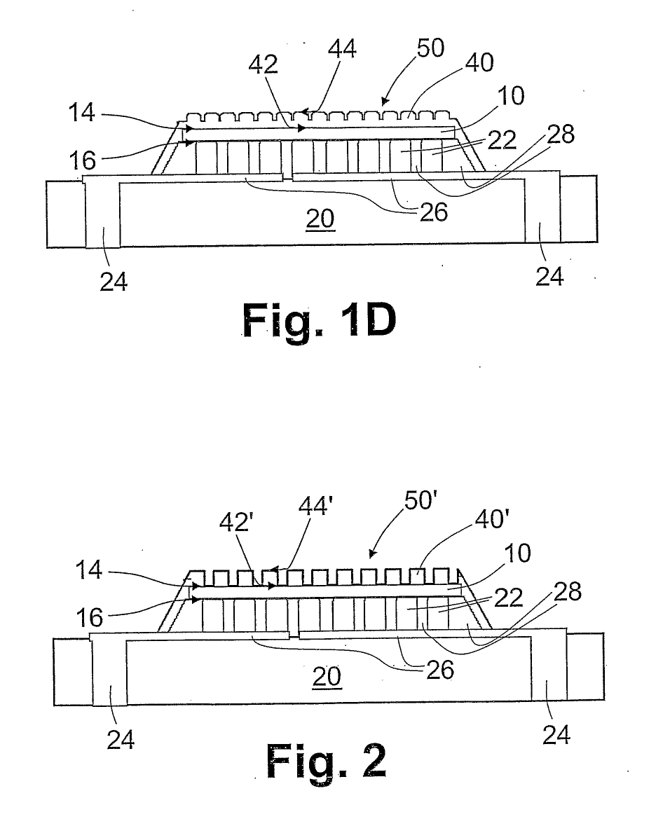

With reference to FIG. 2, in other embodiments a dielectric layer 40′ is disposed over the stack of semiconductor layers 10. The dielectric layer 40′ is substantially transparent to light emitted by the stack of semiconductor layers 10, and has a refractive index that substantially matches a refractive index of the stack of semiconductor layers 10. The dielectric layer 40′ includes a proximate principal surface 42′ that is in contact with the stack of semiconductor layers 10, and a distal principal surface 44′ distal from the stack of semiconductor layers 10. The distal principal surface 44′ includes patterning, roughening, or texturing 50′ configured to promote extraction of light generated in the stack of semiconductor layers. The embodiments of FIG. 2 differ from those of FIG. 1D in that the patterning, roughening, or texturing 50′ extends through to the proximate principal surface 42′ so that the proximate principal surface 42′ includes the patterning, roughening, or texturing 50′. The patterning, roughening, or texturing 50′ of the distal principal surface 44′ is defined by the incomplete coverage of the stack of semiconductor layers by the dielectric layer 40′. The openings in the incomplete coverage define the patterning, roughening, or texturing 50′ of the distal principal surface.

In some embodiments, the patterning, roughening, or texturing 50, 50′ is substantially random and non-periodic. In other embodiments, the patterning, roughening, or texturing 50, 50′ defines microlenses. In yet other embodiments, the patterning, roughening, or texturing 50, 50′ has slanted surfaces or other structure that biases extracted light toward a selected viewing angle. The patterning, roughening, or texturing 50, 50′ reduces the planarity of the distal principal surface 44, 44′ to enhance light extraction by reducing total internal reflection and waveguiding effects. The patterning, roughening, or texturing 50, 50′ includes feature sizes that enhance light extraction based on the wavelength of light emitted by the stack of semiconductor layers 10 defining the light emitting pn junction.

The dielectric layer 40, 40′ can be substantially any transparent dielectric material with a refractive index comparable with that of the semiconductor material. One suitable dielectric material is silicon nitride (SiNₓ). The refractive index of SiNₓ depends upon the stoichiometry, and tends to increase with increasing Si/N ratio. The inventors have deposited SiNx by plasma-enhanced chemical vapor deposition (PECVD), and have measured a refractive index of greater than 2.4 at 680 nm. This refractive index is sufficiently high to substantially match the refractive index of GaN at 680 nm, which has been reported to be about 2.3. See Zauner et al., MRS Internet J. Nitride Semicond. Res. 3, 17 (1998), pp. 1-4. Other suitable dielectric materials include, for example, silicon oxides (SiOₓ) and silicon oxynitrides (SiₓN_{y}),

The refractive index of the dielectric layer 40, 40′ should substantially match the refractive index of the stack of semiconductor layers 10 so as to reduce reflections as light passes from the semiconductor material into the dielectric material. The critical angle θ_{c} references to the interface normal for total internal reflection is given by sin(θ_{c})=n_{d}/nₛ where n_{d} is the refractive index of the dielectric layer 40, 40′ and nₛ is the refractive index of the semiconductor. For n_{d≧n}ₛ, total internal reflection does not occur for light passing from the stack of semiconductor layers 10 into the dielectric layer 40, 40′. Accordingly, any dielectric material having a refractive index about the same as, or greater than, the refractive index of the semiconductor material is considered to substantially match the refractive index of the semiconductor material. That is, the condition for the refractive index of the dielectric layer 40, 40′ to substantially match the refractive index of the stack of semiconductor layers 10 is either n_{d}˜dₛ or n_{d}>nₛ.

The dielectric layer 40, 40′ including the distal principal surface 44, 44′ having the patterning, roughening, or texturing 50, 50′ can be produced in various ways. In one approach, the dielectric layer is deposited substantially uniformly across the first principal surface 14 of the stack of semiconductor layers 10. An etch down process, such as a plasma etch, is then applied using a mask to form the patterning, roughening, or texturing 50, 50′. The mask can be a non-contact mask suitable for patterning devices after attachment to the host substrate or sub-mount 20. A non-contact mask suitable for photolithography, x-ray lithography, or e-beam lithography can be used. The mask can be used to form a resist pattern (such as a photoresist pattern) on the deposited dielectric layer; the resist pattern serves to define the etched and unetched regions. Alternatively, the mask can be used as a shadow mask in a directional dry etching process.

Another approach is to deposit small polystyrene members, such as polystyrene spheres, on the surface of the deposited dielectric layer, and using those members or spheres as a plasma etch mask. This approach typically provides a random or non-periodic patterning, roughening, or texturing. Yet another approach for generating the patterning, roughening, or texturing 50 is to use grating lithography. This approach typically provides a periodic roughening.

These etch-down approaches can produce either the patterning, roughening, or texturing 50 which does not pass entirely through the dielectric layer 40, or the patterning, roughening, or texturing 50′ which does pass entirely through the dielectric layer 40′ so as to define openings in the dielectric layer 40′. The difference is merely in how deep the etch-down process penetrates. If etch-down processing is used to produce the dielectric layer 40′ including openings, then an etching is preferably selected that does not attack the semiconductor material making up the stack of semiconductor layers 10.

A lift-off process can also be used to define the patterning, roughening, or texturing 50. The mask is used first to define a resist pattern (such as a photoresist pattern) on the first principal surface 14 of the stack of semiconductor layers 10. The dielectric layer with index of refraction matched to the semiconductor material is then deposited on top of the first principal surface 14 and the resist pattern, followed by a liftoff process that removes the resist pattern along with those portions of the deposited dielectric layer disposed on the resist.

The lift-off process can be readily performed in a manner which does not damage the stack of semiconductor layers 10, so as to produce the dielectric layer 40′ including openings. For example, the resist pattern can be a photoresist pattern produced by light exposure that does not damage the semiconductor material. To produce the dielectric layer 40 using a lift-off process, a continuous layer of dielectric material can be first deposited, followed by masked resist pattern definition on top of the continuous dielectric layer, followed by a second dielectric layer deposition and lift-off of the selected portions of the second dielectric layer.

In yet another approach, the mask is used first to define the resist pattern, and then an etch-down process is used to form pattern directly on the semiconductor material. However, this approach has the disadvantage that the etching of the semiconductor material can damage the stack of semiconductor layers 10, leading to degraded LED performance.

Patterns with desired shapes may be created after patterning. The shapes of the dielectric (or semiconductor) islands and the island array may effectively form microlenses to optimize optical output power. Optionally, selected island shapes and pattern sidewall angles can be formed to engineer viewing angles. Optionally, the distal principal surface 44, 44′ is coated with an anti-reflection coating after patterning to further enhance light extraction efficiency. An anti-reflection coating is particularly useful when the semiconductor refractive index nₛ is high and the dielectric material accordingly has a high refractive index n_{d} substantially matching the high refractive index nₛ of the stack of semiconductor layers.

The invention has been described with reference to the preferred embodiments. Obviously, modifications and alterations will occur to others upon reading and understanding the preceding detailed description. It is intended that the invention be construed as including all such modifications and alterations insofar as they come within the scope of the appended claims or the equivalents thereof

The appended claims follow:

1. A light emitting device comprising:
a stack of semiconductor layers defining a light-emitting pn junction; and
a dielectric layer disposed over the stack of semiconductor layers, the dielectric layer having a refractive index substantially matching a refractive index of the stack of semiconductor layers, the dielectric layer having a principal surface distal from the stack of semiconductor layers, the distal principal surface including patterning, roughening, or texturing configured to promote extraction of light generated in the stack of semiconductor layers.

2. The lighting emitting device as set forth in claim 1, further comprising:
a host substrate or sub-mount on which is disposed the stack of semiconductor layers, the host substrate or sub-mount being different from a deposition substrate on which the stack of semiconductor layers was formed.

3. The light emitting device as set forth in claim 2, wherein the host substrate or sub-mount includes bonding bumps electrically connecting with the stack of semiconductor layers to enable electrical energizing of the light-emitting pn junction.

4. The light emitting device as set forth in claim 2, wherein the host substrate or sub-mount is a silicon substrate or sub-mount.

5. The light emitting device as set forth in claim 2, wherein the stack of semiconductor layers have first and second opposite principal surfaces, the second principal surface being secured to the host substrate, the first principal surface having been secured to the deposition substrate during formation of the stack of semiconductor layers on the deposition substrate.

6. The light emitting device as set forth in claim 1, wherein the light-emitting pn junction includes a multi-quantum well region.

7. The light emitting device as set forth in claim 1, wherein the stack of semiconductor layers include semiconductor layers selected from a group consisting of: a gallium nitride (GaN) layer, an aluminum nitride (AlN) layer, an indium nitride (InN) layer, layers comprising ternary alloys of GaN, AlN, or InN, and layers comprising quaternary alloys of GaN, AlN, and InN.

8. The light emitting device as set forth in claim 7, wherein the light-emitting pn junction includes a multi-quantum well region including a plurality of layers containing InN or alloys thereof.

9. The light emitting device as set forth in claim 1, wherein the dielectric layer does not completely cover the stack of semiconductor layers, the patterning, roughening, or texturing of the distal principal surface being defined by the incomplete coverage of the stack of semiconductor layers.

10. The light emitting device as set forth in claim 1, wherein the dielectric layer includes openings exposing the underlying stack of semiconductor layers, the openings defining the patterning, roughening, or texturing of the distal principal surface.

11. The light emitting device as set forth in claim 1, wherein the dielectric layer has a proximate principal surface contacting the stack of semiconductor layers, the proximate principal surface contacting the stack of semiconductor layers not including the patterning, roughening, or texturing of the distal principal surface.

12. The light emitting device as set forth in claim 1, wherein the patterning, roughening, or texturing of the distal principal surface includes at least one lateral periodicity.

13. The light emitting device as set forth in claim 1, wherein the patterning, roughening, or texturing of the distal principal surface is substantially random and non-periodic.

14. The light emitting device as set forth in claim 1, wherein the patterning, roughening, or texturing defines microlenses.

15. The light emitting device as set forth in claim 1, wherein the patterning, roughening, or texturing biases extracted light toward a selected viewing angle.

16. The light emitting device as set forth in claim 1, further comprising:
an anti-reflection coating disposed on the distal principal surface of the dielectric layer.

17. A method for fabricating a light emitting device, the method comprising:
forming a stack of semiconductor layers defining a light-emitting pn junction; and
disposing a dielectric layer over the stack of semiconductor layers, the dielectric layer having a refractive index substantially matching a refractive index of the stack of semiconductor layers, the dielectric layer having a principal surface distal from the stack of semiconductor layers, the distal principal surface including patterning, roughening, or texturing configured to promote extraction of light generated in the stack of semiconductor layers.

18. The method as set forth in claim 17, wherein the forming comprises:
depositing the stack of semiconductor layers on a deposition substrate.

19. The method as set forth in claim 18, wherein the forming further comprises:
transferring the stack of semiconductor layers from the deposition substrate to a host substrate or sub-mount.

20. The method as set forth in claim 19, wherein the transferring comprises:
detaching the stack of semiconductor layers from the deposition substrate by a laser lift-off process.

21. The method as set forth in claim 19, wherein the transferring comprises:
attaching a second principal surface of the stack of semiconductor layers to the host substrate or sub-mount; and
detaching a first principal surface opposite the second principal surface from the deposition substrate.

22. The method as set forth in claim 21, wherein the detaching comprises:
applying a laser beam to the deposition substrate to the deposition substrate, the laser beam passing through the deposition substrate substantially unattenuated and being absorbed proximate to the first principal surface of the stack of semiconductor layers.

23. The method as set forth in claim 21, wherein the attaching comprises:
attaching the second principal surface of the stack of semiconductor layers to bonding bumps of the host substrate or sub-mount, the bonding effectuating electrical connection of at least some of the bonding bumps with the stack of semiconductor layers to enable electrical energizing of the light-emitting pn junction.

24. The method as set forth in claim 17 wherein the forming comprises:
forming the stack of semiconductor layers including semiconductor layers selected from a group consisting of: a gallium nitride (GaN) layer, an aluminum nitride (AlN) layer, an indium nitride (InN) layer, layers comprising ternary alloys of GaN, AlN, or InN, and layers comprising quaternary alloys of GaN, AlN, and InN.

25. The method as set forth in claim 17, wherein the forming comprises:
forming the pn junction including a multi-quantum well region.

26. The method as set forth in claim 17, wherein the disposing of the dielectric layer over the stack of semiconductor layers comprises:
forming the patterning, roughening, or texturing into the distal principal surface after the disposing of the dielectric layer.

27. The method as set forth in claim 26, wherein the forming of the patterning, roughening, or texturing comprises:
etching away selected portions of the disposed dielectric layer.

28. The method as set forth in claim 27, wherein the selected portions extend to the underlying stack of semiconductor layers to define openings in the disposed dielectric layer.

29. The method as set forth in claim 27, wherein the selected portions do not extend to the underlying stack of semiconductor layers.

30. The method as set forth in claim 27,wherein the selected portions are defined by a mask.

31. The method as set forth in claim 27, wherein the forming of the patterning, roughening, or texturing into the distal principal surface further comprises:
disposing polystyrene members on the disposed dielectric layer, the disposed polystyrene members defining the selected portions.

32. The method as set forth in claim 17, wherein the disposing of the dielectric layer over the stack of semiconductor layers comprises:
disposing the dielectric layer using a lift-off patterning process that defines the patterning, roughening, or texturing.

33. A light emitting device comprising:
a stack of semiconductor layers defining a light-emitting pn junction;
a host substrate or sub-mount on which is disposed the stack of semiconductor layers, the host substrate or sub-mount being different from a deposition substrate on which the stack of semiconductor layers was formed; and
patterning, roughening, or texturing configured to promote extraction of light generated in the stack of semiconductor layers formed on a distal principal surface of the stack of semiconductor layers that is distal from the host substrate or sub-mount.

34. The lighting emitting device as set forth in claim 33, further comprising:
a dielectric layer disposed over the distal principal surface of the stack of semiconductor layers, the dielectric layer having a refractive index substantially matching a refractive index of the stack of semiconductor layers.

35. A method for fabricating a light emitting device, the method comprising:
forming a stack of semiconductor layers defining a light-emitting pn junction on a deposition substrate;
transferring the formed stack of semiconductor layers from the deposition substrate to a host substrate or sub-mount, the transferring exposing a new principal surface of the stack of semiconductor layers that was not exposed when the stack of semiconductor layers was formed on the deposition substrate; and
generating patterning, roughening, or texturing configured to promote extraction of light generated in the stack of semiconductor layers on the new principal surface of the stack of semiconductor layers.

36. The method as set forth in claim 35, wherein the transferring comprises:
detaching the stack of semiconductor layers from the deposition substrate using a laser lift-off process.

37. The method as set forth in claim 35, further comprising:
disposing a dielectric layer disposed on the new principal surface including on the patterning, roughening, or texturing.
